(19) United States
(12) Patent Application Publication
(10) Pub. No.: US 2010/0162952 A1
(43) Pub. Date: Jul. 1, 2010

(54) Substrate processing apparatus

(75) Inventor: Hirohisa Yamazaki, Toyama-shi (JP)

Correspondence Address: BIRCH STEWART KOLASCH & BIRCH, PO BOX 747, FALLS CHURCH, VA, 22040-0747, US

(73) Assignee: HITACHI KOKUSAI ELECTRIC INC., TOKYO (JP)

(21) Appl. No.: 11/989,890

(22) PCT Filed: Sep. 26, 2006
(86) PCT No.: PCT/JP2006/319067

§ 371 Date: Feb. 1, 2008

(30) Foreign Application Priority Data
Sep. 27, 2005 (JP) 2005-279836

(51) Int. Cl. H01L 21/316

(52) U.S. Cl. 118/692; 257/E21.28

(57) ABSTRACT

Disclosed is a substrate processing apparatus, including a reaction tube to process a substrate therein, wherein the reaction tube includes an outer tube, an inner tube disposed inside the outer tube, and a support section to support the inner tube, the inner tube and the support section are made of quartz or silicon carbide, and a shock-absorbing member is provided between the support section and the inner tube.

### TECHNICAL FIELD

The present invention relates to a substrate processing apparatus, and more particularly, to a semiconductor producing apparatus which produces a semiconductor device such as an IC from a wafer such as a silicon.

### BACKGROUND ART

A semiconductor producing apparatus carries out ALD (atomic layer deposition) film formation in which a wafer is alternately irradiated with a main raw material and a reaction gas obtained by oxidizing or nitriding the main raw material.

When forming an Al₂O₃ (aluminum oxide) film for example, it is possible to form a high quality film at a low temperature in a range of 250 to 450° C. by alternately supplying TMA (Al(CH₃)₃, trimethylaluminum) which is the main raw material and oxidizing reaction gas O₃ (ozone) using the ALD method. According to the ALD method, a film is formed by alternately supplying a plurality of kinds of reaction gases one by one. The film thickness is controlled based on the number of cycles of the supply of reaction gas. If a film forming speed is 1 Å/cycle, in order to form a film of 20 Å, 20 cycles are needed.

According to the semiconductor producing apparatus capable of carrying out the ALD (atomic layer deposition) film formation in which a wafer is alternately irradiated with a main raw material and a reaction gas obtained by oxidizing or nitriding the main raw material, there is a problem that a reaction product adheres to an inside of a diaphragm sensor which measures a pressure in a processing chamber. If the reaction product adheres to the inside of the diaphragm sensor, a zero point of the diaphragm sensor, i.e., a Base pressure is shifted to a plus direction or a minus direction. Hence, there is a problem that an actually desired pressure cannot be obtained and the pressure cannot appropriately be controlled.

It is, therefore, a main object of the present invention to provide a substrate processing apparatus capable of preventing or restraining a reaction product from adhering to a pressure measuring section such as a diaphragm sensor, and capable of precisely measuring a pressure in a processing chamber by the pressure measuring section.

### DISCLOSURE OF INVENTION

According to one aspect of the present invention, there is provided a substrate processing apparatus to form a desired thin film on a substrate, comprising:

a processing chamber to accommodate a substrate therein;

a gas supply section to supply at least two kinds of gases into the processing chamber;

a gas exhaust section to exhaust an atmosphere in the processing chamber;

a control section to control the gas supply section and the gas exhaust section such that the at least two kinds of gases are alternately and repeatedly supplied to and exhausted from the processing chamber predetermined times; and

pressure measuring sections which are in communication with a space whose pressure is to be measured through on-off valves, respectively, to measure a pressure in the processing chamber, the number of the pressure measuring sections being equal to the number of the kinds of the gases to be supplied to the processing chamber, wherein

when measuring the pressure in the processing chamber, the control section controls opening and closing of the respective on-off valves so that each of the pressure measuring sections is used exclusively for a corresponding gas of the at least two kinds of gases.

According to another aspect of the present invention, there is provided a substrate processing apparatus to form a desired thin film on a substrate, comprising:

a processing chamber to accommodate a substrate therein;

a gas supply section to supply at least two kinds of gases into the processing chamber;

a gas exhaust section to exhaust an atmosphere in the processing chamber;

a control section to control the gas supply section and the gas exhaust section such that the at least two kinds of gases are alternately and repeatedly supplied to and exhausted from the processing chamber predetermined times; and

a pressure measuring section which is in communication with a space whose pressure is to be measured through an on-off valve to measure a pressure in the processing chamber, wherein

the control section controls opening and closing of the on-off valve so that the pressure measuring section is used for measuring a pressure in the processing chamber when one of the at least two kinds of gases is supplied to or exhausted from the processing chamber.

### BRIEF DESCRIPTION OF DRAWINGS

FIG. 1 is a schematic vertical sectional view of a vertical type substrate processing furnace in a substrate processing apparatus according to one embodiment of the present invention;

FIG. 2 is a schematic transverse sectional view of the vertical type substrate processing furnace in the substrate processing apparatus according to the embodiment of the present invention;

FIG. 3A is a schematic diagram for explaining a nozzle 233 of the vertical type substrate processing furnace in the substrate processing apparatus according to the embodiment of the present invention;

FIG. 3B is a partial enlarged view of a portion A in FIG. 3A;

FIG. 4 is a diagram for explaining a processing sequence in the vertical type substrate processing furnace in the substrate processing apparatus according to the embodiment of the present invention; and

FIG. 5 is a schematic perspective view for explaining the substrate processing apparatus according to the embodiment of the present invention.

### BEST MODE FOR CARRYING OUT THE INVENTION

Next, preferred embodiments of the present invention will be explained.

In the preferred embodiments of the present invention, if a pressure control monitor comprising a diaphragm sensor is used in a semiconductor producing apparatus capable of carrying out the ALD (atomic layer deposition) film formation in which a wafer is alternately irradiated with a main raw material constituting a certain film kind and a reaction gas obtained by oxidizing or nitriding the main raw material, the semiconductor producing apparatus includes a diaphragm sensor for the main raw material and a diaphragm sensor for the reaction gas obtained by oxidizing or nitriding the main raw material. When the main raw material flows, the diaphragm sensor for the main raw material is used, the reaction gas does not flow, and the diaphragm sensor for the reaction gas is not used. When the reaction gas flows, there is used a sequence in which the diaphragm sensor for the reaction gas is used, the main raw material does not flow, and the diaphragm sensor for the main raw material is not used.

When the main raw material flows, the diaphragm sensor for the main raw material is used, the reaction gas does not flow, and the diaphragm sensor for the reaction gas is not used. Therefore, since the diaphragm sensor for the reaction gas is not exposed to the main raw material, the film formation does not proceed, and a reaction product is not produced. When the reaction gas flows, the diaphragm sensor for the reaction gas is used, the main raw material does not flow, and the diaphragm sensor for the main raw material is not used. Therefore, since the diaphragm sensor for the main raw material is not exposed to the reaction gas, the film formation does not proceed, and a reaction product is not produced.

Next, preferred embodiments of the present invention will be explained in more detail with reference to the drawings.

A semiconductor producing apparatus of the preferred embodiments of the present invention is an ALD film forming apparatus which uses trimethylaluminum (TMA) as a main raw material and uses ozone (O₃) as oxidized species in a vertical type decompressor. The film formation proceeds by alternately supplying TMA and O₃ into a processing chamber.

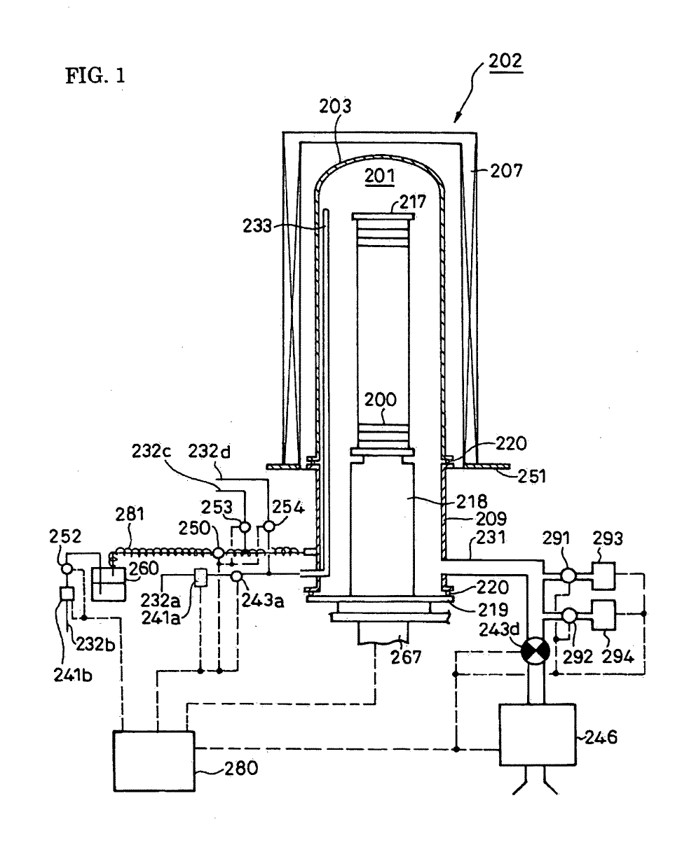

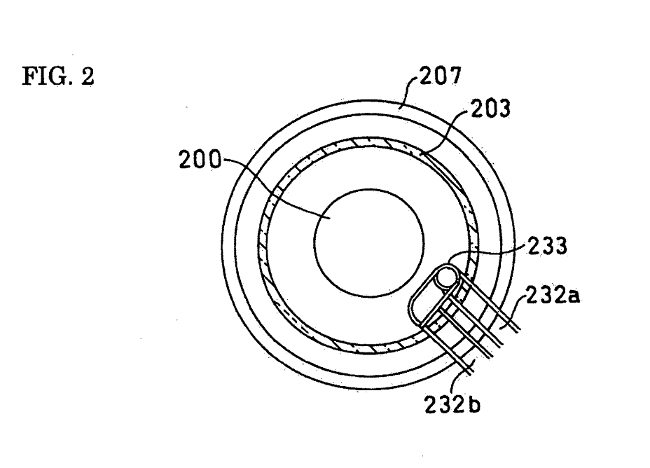

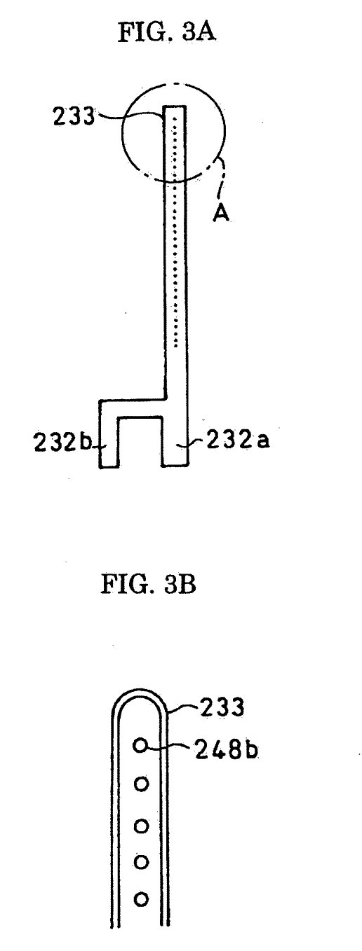

FIG. 1 is a schematic diagram showing a structure of a vertical type substrate processing furnace used in the preferred embodiments of the present invention, and shows a processing furnace 202 in vertical section. FIG. 2 is a schematic diagram showing a structure of the vertical type substrate processing furnace preferably used in the present embodiments, and shows the processing furnace 202 in transverse section. FIG. 3A is a schematic diagram for explaining a nozzle 233 of the vertical type substrate processing furnace in the substrate processing apparatus of the present embodiments. FIG. 3B is a partial enlarged view of a portion A in FIG. 3A.

A reaction tube 203 as a reaction container which processes the wafers 200 as substrates is provided inside a heater 207 which is a heating device (heating means). A manifold 209, which is made of stainless steal etc., is engaged with a lower end of the reaction tube 203. A lower end opening of the manifold 209 is air-tightly closed by a seal cap 219 as a lid through an O-ring 220 which is an air-tight member. The processing chamber 201 is formed by at least the reaction tube 203, the manifold 209 and the seal cap 219. The manifold 209 is fixed to a holding member (heater base 251, hereinafter).

Annular flanges are provided on a lower end of the reaction tube 203 and an upper opening end of the manifold 209, respectively. An air-tight member (O-ring 220, hereinafter) is disposed between these flanges and a gap between the flanges is air-tightly sealed.

A boat 217 which is a substrate holding member (substrate holding means) stands on the seal cap 219 through a boat support stage 218. The boat support stage is a holding body which holds the boat 217. The boat 217 is inserted into the processing chamber 201. A plurality of wafers 200 which are to be subjected to batch process are stacked on the boat 217 in a horizontal attitude in multi-layers in the axial direction of the tube. The heater 207 heats the wafers 200 inserted into the processing chamber 201 to a predetermined temperature.

Two gas supply tubes 232a and 232b as supply paths are provided for supplying a plurality of kinds of (here, two kinds of) gases to the processing chamber 201. The gas supply tubes 232a and 232b penetrate a lower portion of the manifold 209. The gas supply tube 232b joins the gas supply tube 232a in the processing chamber 201, and the two gas supply tubes 232a and 232b are in communication with a single multihole nozzle 233. The nozzle 233 is provided in the processing chamber 201. An upper portion of the nozzle 233 extends to a region having a temperature equal to or higher than a decomposition temperature of TMA which is supplied from the gas supply tube 232b. However, a location where the gas supply tube 232b joins the gas supply tube 232a in the processing chamber 201 is a region whose temperature is lower than the decomposition temperature of TMA, and the temperature of this region is lower than a temperature of the wafers 200 and a temperature around the wafers 200. Here, a reaction gas (ozone: O₃) is supplied from the first gas supply tube 232a to the processing chamber 201 through a first mass flow controller 241a which is a flow rate control device (flow rate control means), a first valve 243a which is an on-off valve, and a later-described multihole nozzle 233 disposed in the processing chamber 201. A main raw material (trimethylaluminum: TMA) is supplied from the second gas supply tube 232b to the processing chamber 201 through a second mass flow controller 241b which is a flow rate control device (flow rate control means), a second valve 252 which is an on-off valve, a TMA container 260, a third valve 250 which is an on-off valve, and the above-described multihole nozzle 233. The gas supply tube 232b from the TMA container 260 to the manifold 209 is provided with a heater 281, and the temperature of the gas supply tube 232b is maintained at 50 to 60° C.

An inert gas line 232c is connected to the gas supply tube 232b on a downstream side of the third valve 250 through an on-off valve 253. An inert gas line 232d is connected to the gas supply tube 232a on a downstream side of the first valve 243a through an on-off valve 254.

The processing chamber 201 is connected to a vacuum pump 246 which is exhaust means through a gas exhaust tube 231 for exhausting gas and a fourth valve 243d so that the processing chamber 201 can be evacuated. The fourth valve 243d is an on-off valve capable of evacuating the processing chamber 201 and stopping the evacuation by opening and closing the fourth valve 243d, and capable of adjusting the pressure in the processing chamber 201 by adjusting valve opening.

A diaphragm sensor 293 is connected to the gas exhaust tube 231 through a baratron protection air valve 291. A diaphragm sensor 294 is connected to the gas exhaust tube 231 through a baratron protection air valve 292.

The nozzle 233 is disposed along a stacking direction of the wafers 200 from a lower portion to an upper portion of the reaction tube 203. The nozzle 233 is provided with gas supply holes 248b which are supply holes through which a plurality of gases are supplied.

The boat 217 is provided at a central portion in the reaction tube 203. The plurality of wafers 200 are placed on the boat 217 at equal distances from one another in multi-layers. The boat 217 can come into and go out from the reaction tube 203 by a boat elevator mechanism (not shown). To enhance the processing uniformity, a boat rotating mechanism 267 which is a rotating device (rotating means) is provided for rotating the boat 217. The boat 217 supported by the boat support stage 218 is rotated by driving the boat rotating mechanism 267.

A controller 280 which is a control section (control means) is connected to the first and second mass flow controllers 241a and 241b, the first to fourth valves 243a, 252, 250 and 243d, the valves 253, 254, 291 and 292, the heater 207, the vacuum pump 246, the diaphragm sensors 293 and 294, the boat rotating mechanism 267 and the boat elevator mechanism (not shown). The controller 280 controls adjustment of flow rates of the first and second mass flow controllers 241a and 241b, controls the opening and closing operations of the first to third valves 243a, 252 and 250, and the valves 253, 254, 291 and 292, controls the measurement by the diaphragm sensors 293 and 294, controls the opening and closing operations and adjusting operation of pressure of the fourth valve 243d, controls adjustment of temperature of the heater 207, controls the actuation and stop of the vacuum pump 246, controls the adjustment of the rotation speed of the boat rotating mechanism 267, and controls the vertical movement of the boat elevator mechanism.

Next, film formation of Al₂O₃ using TMA and O₃ gases will be explained as an example of film formation using the ALD method. This film formation is one of production processes of a semiconductor device.

According to the ALD (Atomic Layer Deposition) method which is one of CVD (Chemical Vapor Deposition) methods, two kinds (or more) of raw material gases used for forming films are alternately supplied onto substrates one by one under given film forming conditions (temperature, time, etc.), the gases are adsorbed on an atom-layer basis, and films are formed utilizing surface reaction.

When forming the Al₂O₃ (aluminum oxide) film as in the present embodiment, a high quality film can be formed at a low temperature in a range of 250 to 450° C. by alternately supplying TMA (Al(CH₃)₃, trimethylaluminum) and O₃ (ozone) using the ALD method.

First, the boat 217 is charged with the semiconductor silicon wafers 200 on which films are to be formed, and the boat 217 is loaded into the processing chamber 201. After the loading, the following four steps are sequentially executed.

In this embodiment, N₂ is used as an inert gas, and N₂ is used as a TMA carrier gas.

(Step 1)

In step 1, TMA gas flows. The TMA is liquid at room temperature. To supply the TMA gas to the processing chamber 201, there are a method in which the TMA is heated, vaporized, and then, supplied, and a method in which an inert gas such as nitrogen and a rare gas called a carrier gas is sent into the TMA container 260, and the vaporized gas is supplied into a processing furnace together with the carrier gas. The latter method will be explained as an example. Here, N₂ is used as the carrier gas.

First, the valve 252 provided in the carrier gas supply tube 232b, the valve 250 provided between the TMA container 260 and the processing chamber 201, and the fourth valve 243d provided in the gas exhaust tube 231 are opened. A carrier gas whose flow rate is adjusted by the second mass flow controller 241b flows from the carrier gas supply tube 232b through the TMA container 260. A mixed gas of TMA and the carrier gas is supplied into the processing chamber 201 from the gas supply holes 248b of the nozzle 233. At the same time, the mixed gas is exhausted from the gas exhaust tube 231.

When the TMA flows, the valve 291 is opened, and a pressure in the processing chamber 207 is monitored by the diaphragm sensor 293. At the same time, the valve 292 is closed so that the TMA gas does not enter the diaphragm sensor 294.

When the TMA gas flows, the fourth valve 243d is appropriately adjusted to keep a pressure in the processing chamber 201 in a range of 10 to 900 Pa, e.g., at 60 Pa. A supply flow rate of the carrier gas controlled by the second mass flow controller 241a is 2 slm. A flow rate of TMA is 0.35 slm. Time during which the TMA is supplied is set to 1 to 4 seconds. Thereafter, time during which the wafers are exposed to the increased pressure atmosphere may be set to 0 to 4 seconds for allowing the gas to be adsorbed. The wafer temperature at that time is maintained at a desired value within a range of 250 to 450° C.

At the same time, if an inert gas flows from the inert gas line 232d which is connected to an intermediate portion of the gas supply tube 232a by opening the on-off valve 254, it is possible to prevent the TMA gas from flowing around to the O₃ side.

Then, the valve 250 is closed, the fourth valve 243d is opened to evacuate the processing chamber 201, and remaining TMA gas after contributing to the film formation is removed. At that time, if an inert gas such as N₂ is supplied to the processing chamber 201 from the first gas supply tube 232a which is an O₃ supply line and from the second gas supply tube 232b which is a TMA supply line, the effect for removing the remaining TMA from the processing chamber 201 is enhanced.

(Step 2)

In step 2, the valve 250a is closed to stop the TMA supply. The fourth valve 243d of the gas exhaust tube 231 is left open, the processing chamber 201 is evacuated by the vacuum pump 246 so that pressure of the processing chamber 201 is reduced to 20 Pa or lower, and the remaining TMA is exhausted from the processing chamber 201. At that time, if an inert gas such as N₂ is supplied to the processing chamber 201 from the second gas supply tube 232b which is a TMA supply line and from the first gas supply tube 232a which is an O₃ supply line, the effect for exhausting the remaining TMA is further enhanced.

In step 2, the valve 291 is opened, and a pressure in the processing chamber 207 is monitored by the diaphragm sensor 293, whereas the valve 292 is closed.

(Step 3)

In step 3, O₃ gas flows. First, the first valve 243a provided in the first gas supply tube 232a and the fourth valve 243d provided in the gas exhaust tube 231 are both opened. Then, O₃ gas whose flow rate is adjusted by the first mass flow controller 243a of the first gas supply tube 232a is supplied to the processing chamber 201 from the gas supply holes 248b of the nozzle 233. At the same time, the O₃ gas is exhausted from the gas exhaust tube 231. When the O₃ gas flows, the fourth valve 243d is appropriately adjusted to keep a pressure in the processing chamber 201 in a range of 10 to 100 Pa, e.g., at 100 Pa. A supply flow rate of O₃ controlled by the first mass flow controller 241a is in a range of 1 to 10 slm, e.g., 5 slm. The wafers 200 are exposed to O₃ for 2 to 120 seconds. The temperature of the heater 207 at that time is set such that the temperature of the wafers is in a range of 250 to 450° C., e.g., 400° C.

When the O₃ gas flows, the valve 292 is opened, and a pressure in the processing chamber 207 is monitored by the diaphragm sensor 294. The valve 291 is closed so that the O₃ gas does not enter the diaphragm sensor 293.

At the same time, if an inert gas flows from the inert gas line 232c which is connected to an intermediate portion of the gas supply tube 232b by opening the on-off valve 253, it is possible to prevent the O₃ gas from flowing around to the TMA side.

By supplying O₃, the O₃ and the TMA which is absorbed on surfaces of the wafers 200 react with each other, and Al₂O₃ films are formed on the wafers 200.

(Step 4)

In step 4, the first valve 243a of the first gas supply tube 232a is closed and supply of the O₃ is stopped. The fourth valve 243d of the gas exhaust tube 231 is left open, the processing chamber 201 is evacuated by the vacuum pump 246 so that pressure of the processing chamber 201 is reduced to 20 Pa or lower, and remaining O₃ is exhausted from the processing chamber 201. At that time, if an inert gas such as N₂ is supplied to the processing chamber 201 from the first gas supply tube 232a which is the O₃ supply line and from the second gas supply tube 232b which is the TMA supply line, the effect for exhausting the remaining O₃ is further enhanced.

In step 4, the valve 292 is opened, and a pressure in the processing chamber 207 is monitored by the diaphragm sensor 294, whereas the valve 291 is closed.

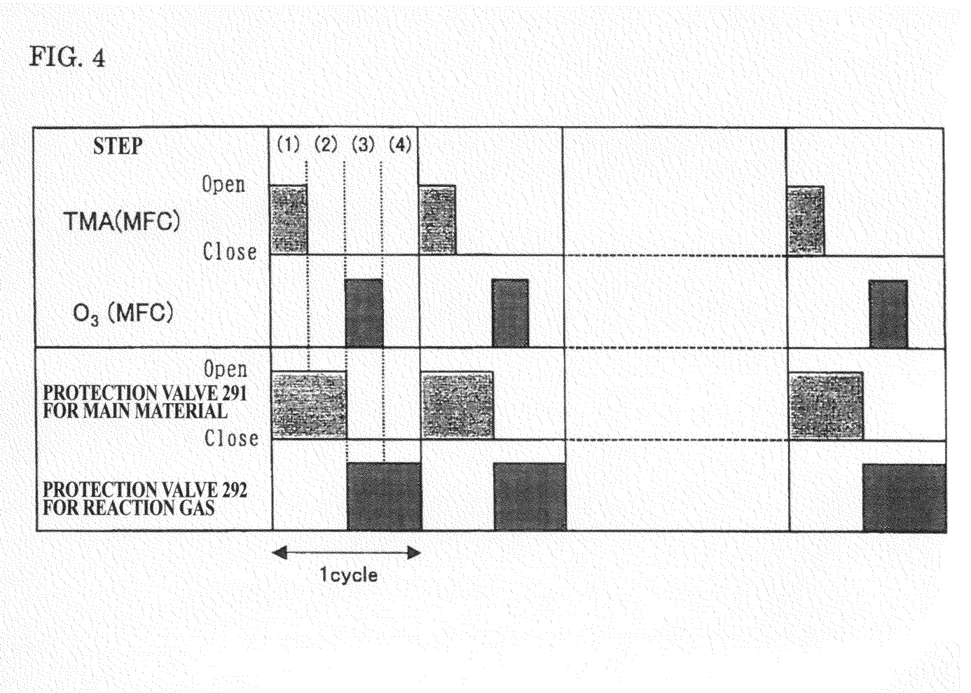

The steps 1 to 4 are defined as one cycle. If this cycle is repeated a plurality of times, Al₂O₃ films having predetermined film thickness can be formed on the wafers 200. The above-described sequence is shown in FIG. 4.

When the TMA flows, the valve 291 is opened, and a pressure in the processing chamber 207 is monitored by the diaphragm sensor 293. The valve 292 is closed so that the TMA gas does not enter the diaphragm sensor 294. When the O₃ gas flows, the valve 292 is opened, and a pressure in the processing chamber 207 is monitored by the diaphragm sensor 294. The valve 291 is closed so that the O₃ gas does not enter the diaphragm sensor 293.

When the TMA of the main raw material flows, the diaphragm sensor 293 for the main raw material TMA is used, the reaction gas (O₃ gas) does not flow and the valve 292 is closed. Therefore, the diaphragm sensor 294 for the reaction gas (O₃ gas) is not exposed to the TMA as the main raw material and thus, the film formation does not proceed, and a reaction product is not generated in the diaphragm sensor. When the reaction gas (O₃ gas) flows, the diaphragm sensor 294 for the reaction gas (O₃ gas) is used, the main raw material TMA does not flow and the valve 291 is closed. Therefore, the diaphragm sensor for the main raw material TMA is not exposed to the reaction gas (O₃ gas) and thus, the film formation does not proceed, and a reaction product is not generated in the diaphragm sensor. As mentioned above, it is possible to prevent a reaction product from being deposited in the diaphragm sensor. Therefore, it is possible to prevent a zero point of the diaphragm sensor from being deviated, and to prevent a prevention pressure shift.

Although the pressure is monitored both when the main raw material TMA flows and when the reaction gas (O₃ gas) flows in the above-described embodiment, if a pressure control monitor for one of the gases is needed, only one diaphragm sensor may be provided as a pressure monitor for one of the gases.

Since the first gas supply tube 232a which is the O₃ supply line and the second gas supply tube 232b which is the TMA supply line join together in the processing chamber 201, the TMA and O₃ can alternately be adsorbed and can react with each other to deposit an Al₂O₃ film in the nozzle 233. Thus, it is possible to eliminate a problem that when TMA and O₃ are supplied through different nozzles, an Al film which may become a generation source of foreign material in the TMA nozzle is generated. Because the Al₂O₃ film has more excellent adhesion than the Al film and is less prone to be peeled off, the Al₂O₃ film does not easily become the generation source of foreign material.

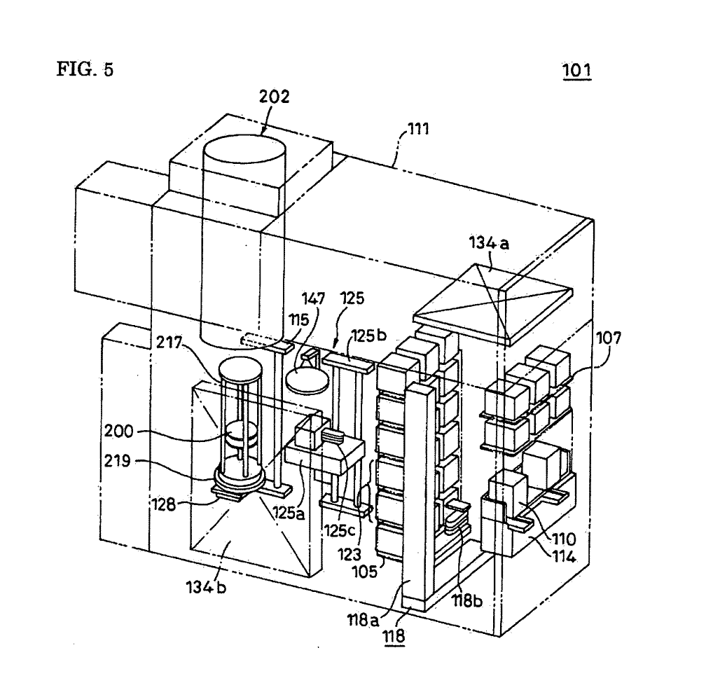

Next, a substrate processing apparatus according to one preferred embodiment of the present invention will be explained with reference to FIG. 5.

In the preferred embodiment of the present invention, the substrate processing apparatus is constituted as a semiconductor producing apparatus which executes processing steps in a producing method of a semiconductor device as one example. FIG. 5 is a schematic perspective view for explaining the substrate processing apparatus of the embodiment.

A processing apparatus 101 of the preferred embodiment uses cassettes 110 as wafer carriers which accommodate wafers (substrates) 200 made of silicon. The processing apparatus 101 includes a casing 111 having a front wall (not shown). A front maintenance opening (not shown) as an opening is formed at a lower portion of the front wall so that maintenance can be carried out. A front maintenance door (not shown) is provided for opening and closing the front maintenance opening (not shown). A cassette carry in/out opening (a substrate container carry in/out opening) (not shown) is formed at the maintenance door (not shown) so that an inside and an outside of the casing 111 are in communication through the cassette carry in/out opening (not shown). The cassette carry in/out opening (not shown) is opened and closed by a front shutter (substrate container carry in/out opening open/close mechanism) (not shown).

A cassette stage (a substrate container delivery stage) 114 is disposed at the cassette carry in/out opening (not shown) inside the casing 111. The cassette 110 is transferred onto the cassette stage 114 by a rail guided vehicle (not shown) and carried out from the cassette stage 114.

The cassette 110 delivered by the rail guided vehicle is placed on the cassette stage 114 such that the wafers 200 in the cassette 110 are in their vertical attitudes and an opening of the cassette 110 for taking wafers in and out is directed upward. The cassette stage 114 is constituted such that it rotates the cassette 110 clockwisely in the vertical direction by 90° to rearward of the casing, the wafers 200 in the cassette 110 are in their horizontal attitudes, and the opening of the cassette 110 for taking wafers in and out is directed to rearward of the casing.

Cassette shelves (substrate container placing shelves) 105 are disposed substantially at a central portion in the casing 111 in its longitudinal direction, and the cassette shelves 105 store a plurality of cassettes 110 in a plurality of rows and a plurality of lines. The cassette shelves 105 are provided with transfer shelves 123 in which the cassettes 110 to be transferred by a wafer loading mechanism 125 are to be accommodated.

Auxiliary cassette shelves 107 are provided above the cassette stage 114 to subsidiarily store the cassettes 110.

A cassette transfer device (a substrate container transfer device) 118 is provided between the cassette stage 114 and the cassette shelves 105. The cassette transfer device 118 includes a cassette elevator (a substrate container elevator mechanism) 118a capable of vertically moving while holding the cassette 110, and a cassette transfer mechanism (a substrate container transfer mechanism) 118b as a transfer mechanism. The cassette transfer device 118 transfers the cassette 110 between the cassette stage 114, the cassette shelves 105 and the auxiliary cassette shelves 107 by a continuous motion of the cassette elevator 118a and the cassette transfer mechanism 118b.

A wafer loading mechanism (a substrate transfer mechanism) 125 is provided behind the cassette shelves 105. The wafer loading mechanism 125 includes a wafer loading device (a substrate loading device) 125a which can rotate or straightly move the wafer 200 in the horizontal direction, and a wafer loading device elevator (a substrate loading device elevator mechanism) 125b which vertically moves the wafer loading device 125a. The wafer loading device elevator 125b is provided on a right end of the pressure-proof casing 111. Tweezers (a substrate holding body) 125c of the wafer loading device 125a as a placing portion of the wafers 200 charges a boat (a substrate holding tool) 217 with wafers 200 and discharges the wafers 200 from the boat 217 by continuous motion of the wafer loading device elevator 125b and the wafer loading device 125a.

A processing furnace 202 is provided at a rear and upper portion in the casing 111. A lower end of the processing furnace 202 is opened and closed by a furnace opening shutter (a furnace opening open/close mechanism) 147.

A boat elevator (a substrate holding tool elevator mechanism) 115 is provided below the processing furnace 202 as an elevator mechanism for vertically moving the boat 217 to and from the processing furnace 202. A seal cap 219 as a lid is horizontally set up on an arm 128 as a connecting tool connected to an elevating stage of the boat elevator 115. The seal cap 219 vertically supports the boat 217, and can close a lower end of the processing furnace 202.

The boat 217 includes a plurality of holding members, and horizontally holds a plurality of wafers 200 (e.g., about 50 to 150 wafers) which are arranged in the vertical direction such that centers thereof are aligned with each other.

A clean unit 134a is provided above the cassette shelves 105. The clean unit 134a includes a dustproof filter and a supply fan for supplying clean air which is a purified atmosphere so that the clean air flows into the casing 111.

A clean unit 134b comprising a supply fan for supplying clean air and a dustproof filter is provided on a left side of the casing 111, i.e. on the opposite side of the wafer loading device elevator 125b and the boat elevator 115. Clean air belched out from the clean unit 134b flows through the wafer loading device 125a and the boat 217, and then is sucked in by an exhaust device (not shown), and is exhausted outside the casing 111.

Next, an operation of the substrate processing apparatus according to the preferred embodiment of the present invention will be explained.

Before the cassette 110 is supplied to the cassette stage 114, the cassette carry in/out opening (not shown) is opened by the front shutter (not shown). Then, the cassette 110 is transferred in from the cassette carry in/out opening (not shown), and is placed on the cassette stage 114 such that the wafers 200 are in their vertical attitudes and the opening of the cassette 110 for taking wafers in and out is directed upward. Then, the cassette 110 is rotated clockwisely in the vertical direction by 90° to rearward of the casing so that the wafers 200 in the cassette 110 are in their horizontal attitudes, and the opening of the cassette 110 for taking wafers in and out is directed to rearward of the casing.

Next, the cassette 110 is automatically transferred onto a designated shelf position of the cassette shelves 105 or the auxiliary cassette shelves 107 by the cassette transfer device 118, and the cassette 110 is temporarily stored. After that, the cassette 110 is transferred onto the transfer shelves 123 from the cassette shelves 105 or the auxiliary cassette shelves 107 by the cassette transfer device 118, or directly transferred onto the transfer shelves 123.

When the cassette 110 is transferred onto the transfer shelves 123, the wafers 200 are picked up from the cassette 110 through the opening by the tweezers 125c of the wafer loading device 125a, and the boat 217 located behind a loading chamber 124 is charged with the wafers 200. The wafer loading device 125a which delivered the wafers 200 to the boat 217 returns to the cassette 110, and charges the boat 217 with the next wafers 200.

When the boat 217 is charged with a predetermined number of wafers 200, a lower end of the processing furnace 202 which was closed by the furnace opening shutter 147 is opened by the furnace opening shutter 147. Then, the boat 217 which holds a group of wafers 200 is loaded into the processing furnace 202 by moving the seal cap 219 upward by the boat elevator 115.

After the loading, the wafers 200 are subjected to processing in the processing furnace 202. After the processing, the wafers 200 and the cassette 110 are carried outside the casing 111 by reversing the above-described procedure.

According to one aspect of the preferred embodiments of the present invention, there is provided a substrate processing apparatus to form a desired thin film on a substrate, comprising:

a processing chamber to accommodate a substrate therein;

a gas supply section to supply at least two kinds of gases into the processing chamber;

a gas exhaust section to exhaust an atmosphere in the processing chamber;

a control section to control the gas supply section and the gas exhaust section such that the at least two kinds of gases are alternately and repeatedly supplied to and exhausted from the processing chamber predetermined times; and

pressure measuring sections which are in communication with a space whose pressure is to be measured through on-off valves, respectively, to measure a pressure in the processing chamber, the number of the pressure measuring sections being equal to the number of the kinds of the gases to be supplied to the processing chamber, wherein

when measuring the pressure in the processing chamber, the control section controls opening and closing of the respective on-off valves so that each of the pressure measuring sections is used exclusively for a corresponding gas of the at least two kinds of gases.

Preferably, the gases include at least a first gas and a second gas,

the pressure measuring sections include a first pressure measuring section used for the first gas and a second pressure measuring section used for the second gas,

the control section controls the gas supply section and the gas exhaust section to repeat following steps predetermined times:

a first supply step of supplying the first gas to the processing chamber;

a first exhaust step of exhausting the first gas which remains in the processing chamber from the processing chamber;

a second supply step of supplying the second gas to the processing chamber; and

a second exhaust step of exhausting the second gas which remains in the processing chamber from the processing chamber, and

the control section further controls the on-off valves

in order to measure the pressure in the processing chamber using the first pressure measuring section in the first supply step and the first exhaust step, and

in order to measure the pressure in the processing chamber using the second pressure measuring section in the second supply step and the second exhaust step.

Preferably, the space whose pressure is to be measured is a space in a gas exhaust tube connected to the processing chamber. Preferably, the pressure measuring section is a diaphragm sensor.

Preferably, the at least two kinds of gases react with each other to form the film. Preferably, the at least two kinds of gases are a trimethylaluminum gas and an ozone gas, and the thin film formed on the substrate is aluminum oxide.

According to another aspect of the preferred embodiments of the present invention, there is provided a substrate processing apparatus to form a desired thin film on a substrate, comprising:

a processing chamber to accommodate a substrate therein;

a gas supply section to supply at least two kinds of gases into the processing chamber;

a gas exhaust section to exhaust an atmosphere in the processing chamber;

a control section to control the gas supply section and the gas exhaust section such that the at least two kinds of gases are alternately and repeatedly supplied to and exhausted from the processing chamber predetermined times; and

a pressure measuring section which is in communication with a space whose pressure is to be measured through an on-off valve to measure a pressure in the processing chamber, wherein

the control section controls opening and closing of the on-off valve so that the pressure measuring section is used for measuring a pressure in the processing chamber when one of the at least two kinds of gases is supplied to or exhausted from the processing chamber.

The entire disclosures of Japanese Patent Application No. 2005-279836 filed on Sep. 27, 2005 including specification, claims, drawings and abstract are incorporated herein by reference in its entirety so far as the national law of any designated or elected State permits in this international application.

Although various exemplary embodiments have been shown and described, the invention is not limited to the embodiments shown. Therefore, the scope of the invention is intended to be limited solely by the scope of the claims that follow.

### INDUSTRIAL APPLICABILITY

As explained above, according to the preferred embodiments of the present invention, it is possible to prevent or restrain a reaction product from adhering to a pressure measuring section such as a diaphragm sensor, and to precisely measure a pressure in a processing chamber by the pressure measuring section.

As a result, the present invention can especially suitably be utilized for a substrate processing apparatus which forms a film on a silicon wafer using an ALD method.

What is claimed is:

1. A substrate processing apparatus, comprising:
a processing chamber to accommodate a substrate therein;
a gas supply section to supply at least two kinds of gases into the processing chamber;
a gas exhaust section to exhaust an atmosphere in the processing chamber;
a control section to control the gas supply section and the gas exhaust section such that the at least two kinds of gases are alternately and repeatedly supplied to and exhausted from the processing chamber predetermined times; and
pressure measuring sections which are in communication with a space whose pressure is to be measured through on-off valves, respectively, to measure a pressure in the processing chamber, the number of the pressure measuring sections being equal to the number of the kinds of the gases to be supplied to the processing chamber, wherein
when measuring the pressure in the processing chamber, the control section controls opening and closing of the respective on-off valves so that each of the pressure measuring sections is used exclusively for a corresponding gas of the at least two kinds of gases.

2. The substrate processing apparatus according to claim 1, wherein
the gases include at least a first gas and a second gas,
the pressure measuring sections include a first pressure measuring section used for the first gas and a second pressure measuring section used for the second gas,
the control section controls the gas supply section and the gas exhaust section to repeat following steps predetermined times:
a first supply step of supplying the first gas to the processing chamber;
a first exhaust step of exhausting the first gas which remains in the processing chamber from the processing chamber;
a second supply step of supplying the second gas to the processing chamber; and
a second exhaust step of exhausting the second gas which remains in the processing chamber from the processing chamber, and
the control section further controls the on-off valves
in order to measure the pressure in the processing chamber using the first pressure measuring section in the first supply step and the first exhaust step, and
in order to measure the pressure in the processing chamber using the second pressure measuring section in the second supply step and the second exhaust step.

3. The substrate processing apparatus according to claim 1, wherein the space whose pressure is to be measured is a space in a gas exhaust tube connected to the processing chamber.

4. The substrate processing apparatus according to claim 3, wherein the pressure measuring section is a diaphragm sensor.

5. The substrate processing apparatus according to claim 1, wherein the at least two kinds of gases react with each other to form the film.

6. The substrate processing apparatus according to claim 5, wherein the at least two kinds of gases are a trimethylaluminum gas and an ozone gas, and the thin film formed on the substrate is aluminum oxide.

7. A substrate processing apparatus, comprising:
a processing chamber to accommodate a substrate therein;
a gas supply section to supply at least two kinds of gases into the processing chamber;
a gas exhaust section to exhaust an atmosphere in the processing chamber;
a control section to control the gas supply section and the gas exhaust section such that the at least two kinds of gases are alternately and repeatedly supplied to and exhausted from the processing chamber predetermined times; and
a pressure measuring section which is in communication with a space whose pressure is to be measured through an on-off valve to measure a pressure in the processing chamber, wherein
the control section controls opening and closing of the on-off valve so that the pressure measuring section is used for measuring a pressure in the processing chamber when one of the at least two kinds of gases is supplied to or exhausted from the processing chamber.
